(19) United States
(12) Patent Application Publication
(10) Pub. No.: US 2026/0148780 A1
(43) Pub. Date: May 28, 2026

(54) FLASH MEMORY DEVICE AND PROGRAMMING METHOD THEREOF

(71) Applicant: Winbond Electronics Corp., Taichung City (TW)

(72) Inventor: Chung-Zen Chen, HsinChu (TW)

(73) Assignee: Winbond Electronics Corp., Taichung City (TW)

(21) Appl. No.: 19/353,620

(22) Filed: Oct. 9, 2025

(30) Foreign Application Priority Data
Nov. 27, 2024 (TW) 113145704

(51) Int. Cl. G11C 16/34; G11C 16/10; G11C 16/32

(52) U.S. Cl. CPC G11C 16/3459; G11C 16/102; G11C 16/32

(57) ABSTRACT

A flash memory device and a programming method thereof are provided. The programming method includes: selecting a target memory area to be performed a programming operation from a plurality of memory areas, wherein the target memory area is divided into a plurality of memory cell groups; performing a programming verification on the target memory area; and in a case where the target memory area fails the programming verification, setting a programming time period of one of the memory cell groups to overlap with a programming time period of another one of the memory cell groups, and sequentially programming the memory cell groups accordingly.

### CROSS-REFERENCE TO RELATED APPLICATION

This application claims the priority benefit of Taiwan application serial no. 113145704, filed on November 27, 2024. The entirety of the above-mentioned patent application is hereby incorporated by reference herein and made a part of this specification.

### BACKGROUND

### TECHNICAL FIELD

The disclosure relates to a control technology for a memory device, and particularly relates to a flash memory device and a programming method thereof.

### Related Art

Flash memory devices can be roughly divided into two types: NOR-type and NAND-type. Compared to NAND-type flash memory devices, NOR-type flash memory devices require a longer time to program. However, NOR-type flash memory devices can provide complete address and data buses, allowing access to any memory cell on the devices. Therefore, how to reduce the time for performing a programming operation on NOR-type flash memory devices has become an important issue in this field.

### SUMMARY

The disclosure provides a flash memory device and a programming method thereof, which reduce the time required for performing a programming operation.

A programming method for a flash memory device according to an embodiment of the disclosure includes: selecting a target memory area to be performed a programming operation from multiple memory areas, in which the target memory area is divided into multiple memory cell groups; performing a programming verification on the target memory area; and in a case where the target memory area fails the programming verification, setting a programming time period of one of the memory cell groups to overlap with a programming time period of another one of the memory cell groups, and sequentially programming the memory cell groups accordingly.

A flash memory device according to an embodiment of the disclosure includes a memory array and a memory control circuit. The memory array has multiple memory areas. The memory control circuit is coupled to the memory array and configured to select a target memory area to be performed a programming operation from the memory areas. The target memory area is divided into multiple memory cell groups. The memory control circuit is configured to perform a programming verification on the target memory area. In a case where the target memory area fails the programming verification, the memory control circuit is configured to set a programming time period of one of the memory cell groups to overlap with a programming time period of another one of the memory cell groups, and sequentially program the memory cell groups accordingly.

Based on the above, the flash memory device and the programming method thereof according to the embodiments of the disclosure set the programming time periods of multiple memory cell groups to overlap with each other, which may reduce the time required for performing a programming operation.

To make the foregoing features and advantages of the disclosure easier to understand, exemplary embodiments of the disclosure will be described in detail below with reference to the accompanying drawings.

### BRIEF DESCRIPTION OF THE DRAWINGS

FIG. 1 is a block diagram illustrating the flash memory device according to an embodiment of the disclosure.

FIG. 2 and FIG. 4 are flowcharts illustrating the programming method for the flash memory device according to some embodiments of the disclosure.

FIG. 3A to FIG. 3D and FIG. 5 illustrate examples of the programming method for the flash memory device according to some embodiments of the disclosure.

### DESCRIPTION OF THE EMBODIMENTS

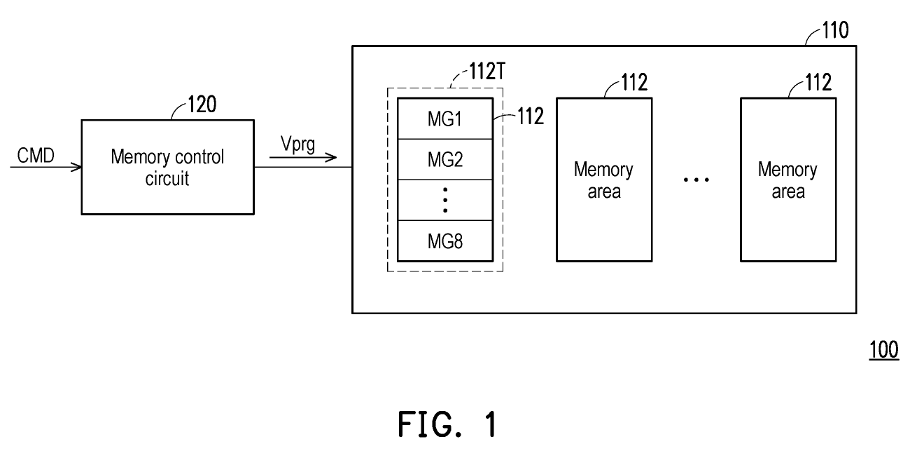

Referring to FIG. 1, a flash memory device 100 according to an embodiment of the disclosure may be a NOR-type flash memory device which includes a memory array 110 and a memory control circuit 120. The memory array 110 has multiple memory areas 112. Each memory area 112 has multiple memory cells. The memory cells of this embodiment may be, for example, ETOX structures. It should be noted that the disclosure is not intended to limit the number of memory areas 112 or the number of memory cells forming one memory area 112.

The memory control circuit 120 is coupled to the memory array 110. The memory control circuit 120 may select a target memory area 112T to be performed a programming operation from the memory areas 112 in the memory array 110 according to the received selection command CMD. In this embodiment, the target memory area 112T may be divided into 8 memory cell groups MG1 to MG8. For example, each of the memory cell groups MG1 to MG8 may correspond to 16 bits. The memory cell group MG1 includes 16 memory cells corresponding to the highest 16 bits in the target memory area 112T, the memory cell group MG2 includes 16 memory cells corresponding to the next 16 bits immediately following the bits of memory cell group MG1 in the target memory area 112T, and so on. Nevertheless, the disclosure is not intended to limit the size of each of the memory cell groups MG1 to MG8 and the number of bits corresponding thereto. Those skilled in the art may make appropriate adjustment according to actual requirements.

In addition to being, for example, a state machine, a central processing unit, or other programmable general-purpose or special-purpose microprocessors, digital signal processors, programmable controllers, application-specific integrated circuits, programmable logic devices, other similar devices, or combinations thereof, the memory control circuit 120 may also be a hardware circuit designed through hardware description languages or any other known digital circuit design methods, and implemented through field-programmable logic gate arrays or complex programmable logic devices. It is worth mentioning that although FIG. 1 shows the memory control circuit 120 located within the flash memory device 100, the memory control circuit 120 may also be a device independent of the flash memory device 100.

For the programming operation of the flash memory device, besides programming time, the programming current flowing from the drain to the source of the memory cells is also an important parameter for reducing power consumption, which is also crucial for green semiconductor technology. When programming a specific number of memory cells, a regulator with a charge pump circuit may be used to provide a stable drain voltage (for example, 4 volts) to the memory cells to generate the programming current, thereby ensuring successful programming.

However, the programming current generated by all the memory cells during programming decreases over time, potentially reducing to only half of the original value, which may result in a waste of the performance of the charge pump circuit. Thus, the disclosure utilizes the aforementioned characteristic to overlap the programming time periods of multiple memory cell groups with each other, under the premise that the peak value of the programming current does not exceed the load capacity of the charge pump circuit, thereby reducing the time required for performing the programming operation.

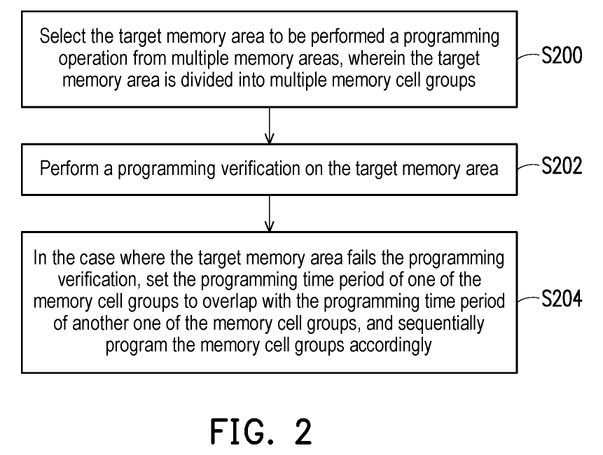

Referring to both FIG. 1 and FIG. 2, the programming method for the flash memory device according to this embodiment is applicable to the flash memory device 100 in FIG. 1. Each step of the programming method according to this embodiment of the disclosure will be described below with reference to the components in the flash memory device 100.

First, in step S200, according to the received selection command CMD, the memory control circuit 120 selects the target memory area 112T to be performed a programming operation from the memory areas 112 in the memory array 110. The target memory area 112T is divided into 8 memory cell groups MG1 to MG8.

Next, in step S202, the memory control circuit 120 performs a programming verification on the target memory area 112T. Specifically, the memory control circuit 120 may compare the bit data (for example, 16 bits) formed by each of the memory cell groups MG1 to MG8 in the target memory area 112T with the corresponding data pattern (for example, 16 bits) to determine whether the memory cell groups MG1 to MG8 in the target memory area 112T all pass the programming verification. More specifically, in an example of the programming verification, the memory control circuit 120 may determine whether the threshold voltage (Vth) of each memory cell in each of the memory cell groups MG1 to MG8 falls within the specified range for each bit value in the corresponding data pattern. If the bit value in the data pattern is “0,” the corresponding threshold voltage should be greater than the preset programming verification reference voltage; and if the bit value in the data pattern is “1,” the corresponding threshold voltage should be less than the preset programming verification reference voltage.

When the threshold voltages of all the memory cells in the memory cell groups MG1 to MG8 fall within the specified range for the bit values in the corresponding data pattern, it indicates that there is no failed memory cell in the memory cell groups MG1 to MG8. That is, the memory cells all pass the programming verification. In this case, the memory control circuit 120 determines that the target memory area 112T passes the programming verification. When there are memory cells in the memory cell groups MG1 to MG8 whose threshold voltages do not fall within the specified range for the bit values in the corresponding data pattern, it indicates that there are failed memory cells in the memory cell groups MG1 to MG8. That is, not all memory cells pass the programming verification. In this case, the memory control circuit 120 determines that the target memory area 112T fails the programming verification. The term “failed memory cell” refers to a memory cell that has failed the programming verification.

Finally, in step S204, in the case where the target memory area 112T fails the programming verification, the memory control circuit 120 sets the programming time period of one of the memory cell groups MG1 to MG8 to overlap with the programming time period of another one of the memory cell groups MG1 to MG8, and sequentially programs the memory cell groups MG1 to MG8 accordingly.

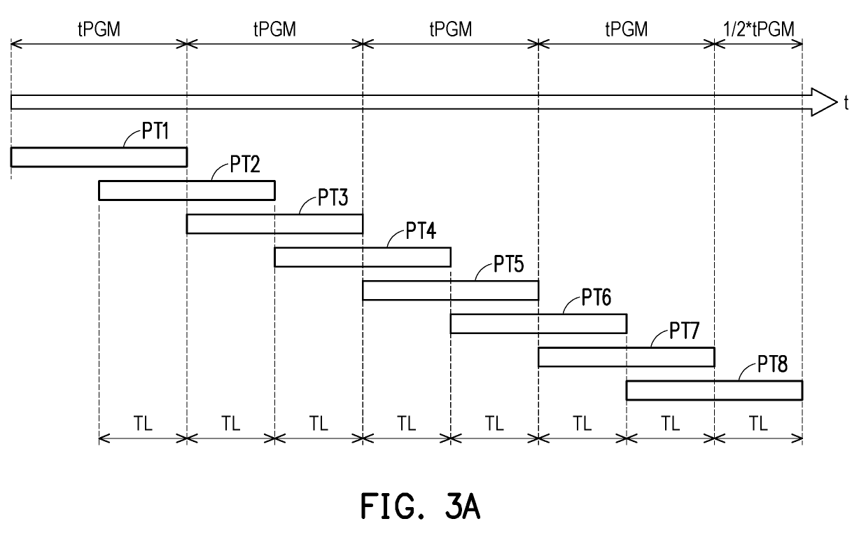

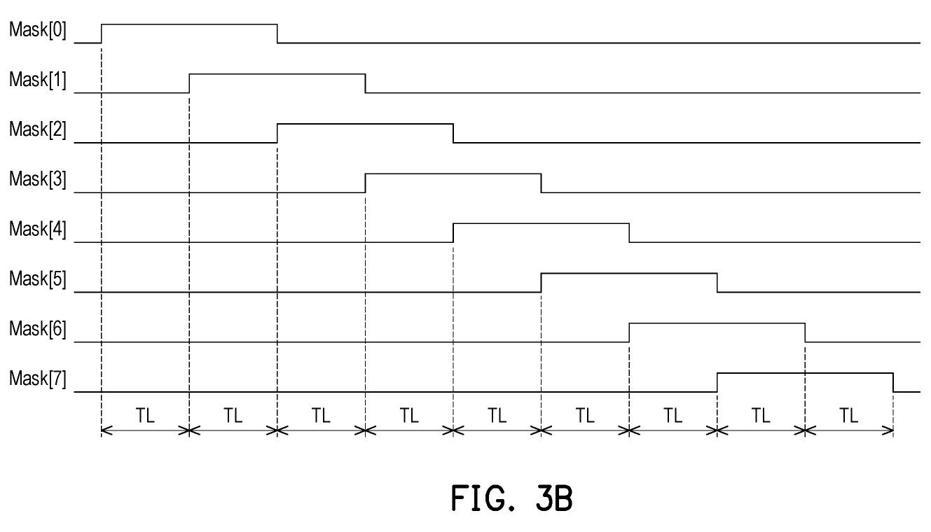

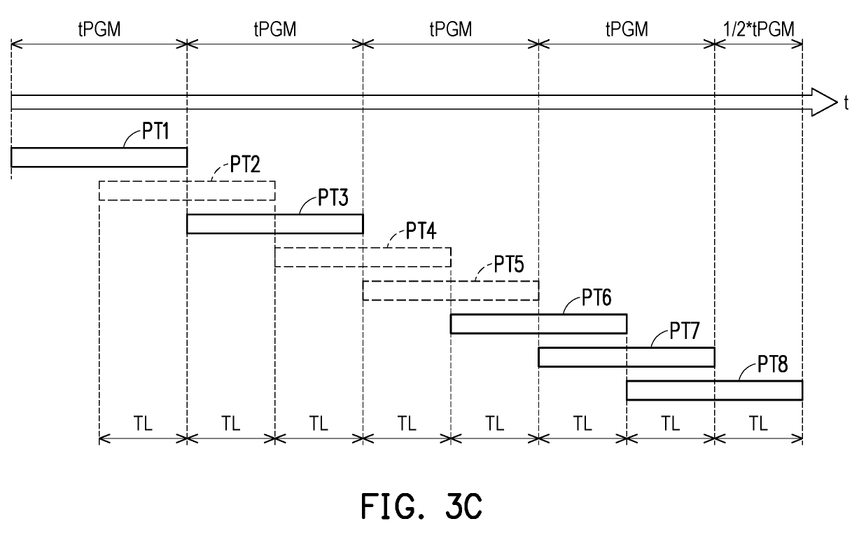

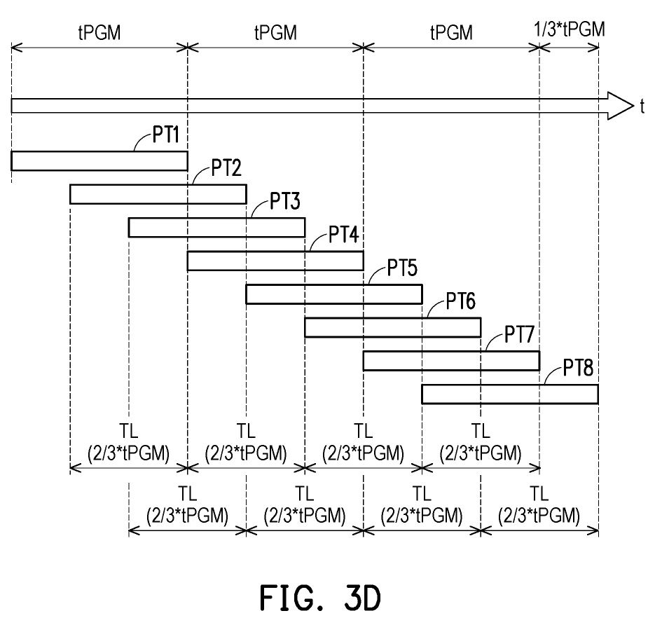

For example, referring to FIG. 3A to FIG. 3C, in the example shown in FIG. 3A to FIG. 3C, the horizontal axis represents time t, and the programming time periods PT1 to PT8 respectively correspond to the memory cell groups MG1 to MG8. The programming time periods PT1 to PT8 have the same duration, which is denoted by tPGM. The memory control circuit 120 may set each of the programming time periods PT1 to PT8 of the memory cell groups MG1 to MG8 to overlap with the programming time period of the preceding memory cell group by a predetermined duration TL. The programming time period PT2 of the memory cell group MG2 is set to overlap with the programming time period PT1 of the memory cell group MG1 by the predetermined duration TL, the programming time period PT3 of the memory cell group MG3 is set to overlap with the programming time period PT2 of the memory cell group MG2 by the predetermined duration TL, and so on. In this embodiment, the predetermined duration TL is half of the duration tPGM.

Assuming that there are failed memory cells in each of the memory cell groups MG1 to MG8 (that is, none of the memory cell groups MG1 to MG8 passes the programming verification), as shown in FIG. 3A, the memory control circuit 120 may sequentially program the memory cell groups MG1 to MG8 that fail the programming verification during the programming time periods PT1 to PT8. Specifically, the memory control circuit 120 applies the programming voltage Vprg to the failed memory cells in the memory cell group MG1 of the target memory area 112T during the programming time period PT1, the memory control circuit 120 applies the programming voltage Vprg to the failed memory cells in the memory cell group MG2 of the target memory area 112T during the programming time period PT2, and so on.

In application, the memory cell groups MG1 to MG8 may respectively correspond to 8 masks Mask[0] to Mask[7]. As shown in FIG. 3B, first, when the mask Mask[0] is opened, the memory control circuit 120 programs only the memory cell group MG1. After the mask Mask[0] has been opened for the predetermined duration TL (equal to half of the duration tPGM), the mask Mask[1] is opened so that the memory control circuit 120 simultaneously programs the memory cell groups MG1 and MG2. After the mask Mask[0] has been opened for twice the predetermined duration TL (equal to the duration tPGM), the mask Mask[0] is closed and the mask Mask[2] is opened so that the memory control circuit 120 simultaneously programs the memory cell groups MG2 and MG3, and so on. In this way, the programming of the memory cell groups MG1 to MG8 is gradually completed.

It should be noted that the programming voltage Vprg includes the voltages applied to the gate node, drain node, source node, and well region of the failed memory cells, particularly referring to the voltage applied to the drain node. For example, the voltage applied to the gate node may be 9 volts, the voltage applied to the drain node may be 4 volts, and the voltage applied to the source node and well region may be 0 volts, but the disclosure is not limited thereto.

Since each of the programming time periods PT1 to PT8 of the memory cell groups MG1 to MG8 is set to overlap with the programming time period of the preceding memory cell group, it is possible to complete one programming operation on the target memory area 112T in only 4.5 times the duration tPGM, thereby reducing the time required for performing the programming operation.

Assuming that only some of the memory cell groups MG1 to MG8 have failed memory cells (for example, only the memory cell groups MG1, MG3, MG6, MG7, and MG8 fail the programming verification), as shown in FIG. 3C, the memory control circuit 120 may sequentially program the memory cell groups MG1, MG3, MG6, MG7, and MG8 that fail the programming verification during the programming time periods PT1, PT3, PT6, PT7, and PT8. Specifically, the memory control circuit 120 respectively applies the programming voltage Vprg to the failed memory cells in the memory cell groups MG1, MG3, MG6, MG7, and MG8 of the target memory area 112T during the programming time periods PT1, PT3, PT6, PT7, and PT8, but does not apply the programming voltage Vprg to the memory cell groups MG2, MG4, and MG5 of the target memory area 112T during the programming time periods PT2, PT4, and PT5 (indicated by dashed lines in FIG. 3C).

Additionally, the predetermined duration TL is not necessarily half of the duration tPGM. Those skilled in the art may adjust the length of the predetermined duration TL according to actual requirements. In an embodiment, as shown in FIG. 3D, the predetermined duration TL that overlaps with the programming time period of the preceding memory cell group is two-thirds of the duration tPGM.

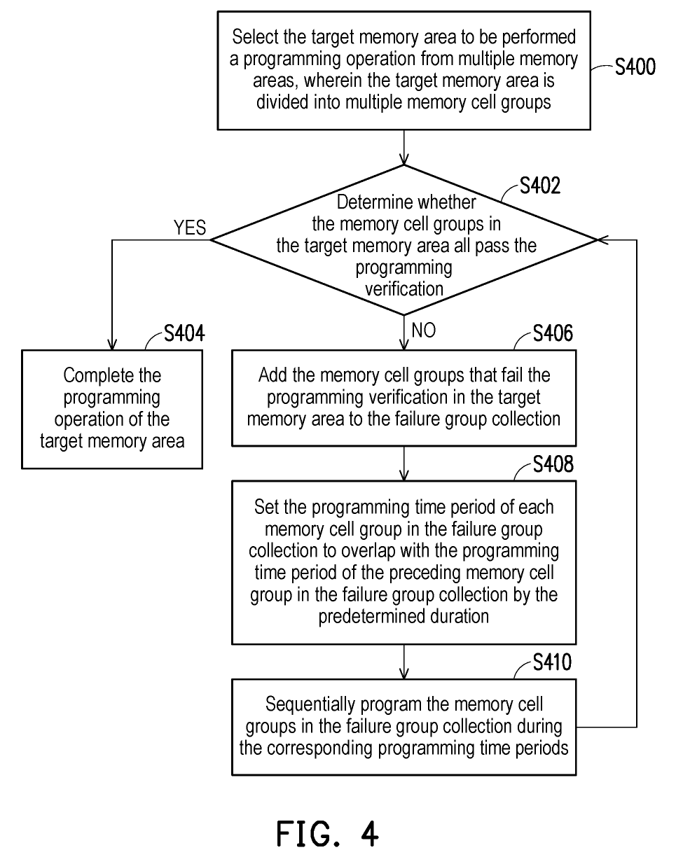

The following is another embodiment that illustrates the programming method according to the disclosure. Referring to FIG. 1 and FIG. 4, the programming method for the flash memory device according to this embodiment is applicable to the flash memory device 100 in FIG. 1. Each step of the programming method according to this embodiment of the disclosure will be described below with reference to the components in the flash memory device 100. In this embodiment, parts that are the same as or similar to the description in FIG. 2 will not be repeated.

First, in step S400, the memory control circuit 120 selects the target memory area 112T to be performed a programming operation from the memory areas 112 in the memory array 110 according to the received selection command CMD. The target memory area 112T is divided into 8 memory cell groups MG1 to MG8.

Next, in step S402, the memory control circuit 120 determines whether the memory cell groups MG1 to MG8 in the target memory area 112T all pass the programming verification. Specifically, the memory control circuit 120 may compare the bit data (for example, 16 bits) formed by each of the memory cell groups MG1 to MG8 in the target memory area 112T with the corresponding data pattern (for example, 16 bits).

When the threshold voltages of all the memory cells in the memory cell groups MG1 to MG8 fall within the specified range for the bit values in the corresponding data pattern, it indicates that there is no failed memory cell in the memory cell groups MG1 to MG8. That is, the memory cells all pass the programming verification. In this case, the memory control circuit 120 determines that the target memory area 112T passes the programming verification, and completes the programming operation of the target memory area 112T in step S404.

When there are memory cells in the memory cell groups MG1 to MG8 whose threshold voltages do not fall within the specified range for the bit values in the corresponding data pattern, it indicates that there are failed memory cells in the memory cell groups MG1 to MG8. That is, not all memory cells pass the programming verification. In this case, the memory control circuit 120 determines that the target memory area 112T fails the programming verification, and proceeds to step S406.

In step S406, the memory control circuit 120 adds the memory cell groups that fail the programming verification in the target memory area 112T to a failure group collection. For example, in the case where only the memory cell groups MG1, MG3, MG6, MG7, and MG8 in the target memory area 112T have failed memory cells and fail the programming verification, the memory control circuit 120 adds the memory cell groups MG1, MG3, MG6, MG7, and MG8 to the failure group collection.

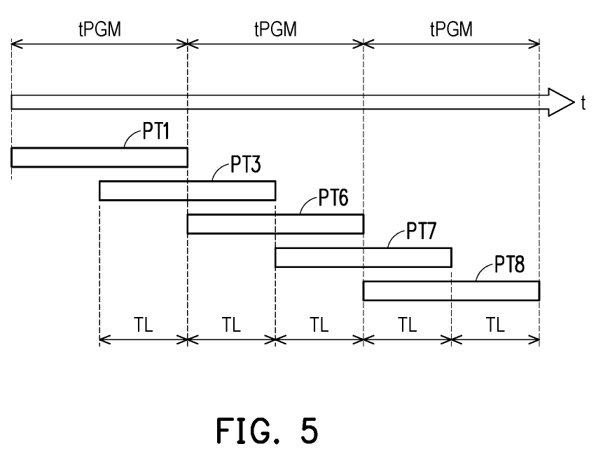

In step S408, the memory control circuit 120 sets the programming time period (for example, programming time periods PT1, PT3, PT6, PT7, and PT8) of each memory cell group (for example, memory cell groups MG1, MG3, MG6, MG7, and MG8) in the failure group collection to overlap with the programming time period of the preceding memory cell group in the failure group collection by the predetermined duration TL. Referring to FIG. 5, in this example, the horizontal axis represents time t, and the programming time periods PT1, PT3, PT6, PT7, and PT8 have the same duration, which is denoted by tPGM. The programming time period PT3 of the memory cell group MG3 is set to overlap with the programming time period PT1 of the memory cell group MG1 by the predetermined duration TL, the programming time period PT6 of the memory cell group MG6 is set to overlap with the programming time period PT3 of the memory cell group MG3 by the predetermined duration TL, the programming time period PT7 of the memory cell group MG7 is set to overlap with the programming time period PT6 of the memory cell group MG6 by the predetermined duration TL, and the programming time period PT8 of the memory cell group MG8 is set to overlap with the programming time period PT7 of the memory cell group MG7 by the predetermined duration TL.

Accordingly, in step S410, the memory control circuit 120 sequentially programs the memory cell groups MG1, MG3, MG6, MG7, and MG8 in the failure group collection during the programming time periods PT1, PT3, PT6, PT7, and PT8 set as shown in FIG. 5. Specifically, the memory control circuit 120 applies the programming voltage Vprg to the failed memory cells in the memory cell group MG1 of the target memory area 112T during the programming time period PT1, the memory control circuit 120 applies the programming voltage Vprg to the failed memory cells in the memory cell group MG3 of the target memory area 112T during the programming time period PT3, and so on.

Then, the memory control circuit 120 may clear the failure group collection, and return to step S402 to continue the programming verification, until all the memory cell groups in the target memory area 112T pass the programming verification.

As such, by taking into account only the programming time periods of the memory cell groups added to the failure group collection each time, it is possible to complete one programming operation on the target memory area 112T in less time, thereby reducing the time required for performing the programming operation.

In summary, the flash memory device and the programming method thereof according to the embodiments of the disclosure set the programming time periods of multiple memory cell groups to overlap with each other, under the premise that the peak value of the programming current does not exceed the load capacity of the charge pump circuit, which not only reduces the time required for performing the programming operation but also fully utilizes the performance of the charge pump circuit. Therefore, the disclosure is beneficial for the application of energy-saving products and is a type of green semiconductor technology.

What is claimed is:

1. A programming method for a flash memory device, which comprises a memory array having a plurality of memory areas, the programming method comprising:
selecting a target memory area to be performed a programming operation from the memory areas, wherein the target memory area is divided into a plurality of memory cell groups;
performing a programming verification on the target memory area; and
in a case where the target memory area fails the programming verification, setting a programming time period of one of the memory cell groups to overlap with a programming time period of another one of the memory cell groups, and sequentially programming the memory cell groups accordingly.

2. The programming method according to claim 1, wherein the memory cell groups respectively correspond to a plurality of masks, and performing the programming verification on the target memory area comprises:
programming only a first one of the memory cell groups in response to a first one of the masks being opened; and
after a predetermined duration has passed since the first one of the masks is opened, opening a second one of the masks to simultaneously program the first one and a second one of the memory cell groups.

3. The programming method according to claim 1, wherein setting the programming time period of one of the memory cell groups to overlap with the programming time period of another one of the memory cell groups comprises:
setting a programming time period of each of the memory cell groups to overlap with a programming time period of a preceding memory cell group by a predetermined duration.

4. The programming method according to claim 3, wherein sequentially programming the memory cell groups accordingly comprises:
sequentially programming the memory cell groups that fail the programming verification during corresponding programming time periods.

5. The programming method according to claim 3, wherein the predetermined duration is half or two-thirds of a length of the programming time period of the memory cell group.

6. The programming method according to claim 1, further comprising:
adding the memory cell groups that fail the programming verification in the target memory area to a failure group collection.

7. The programming method according to claim 6, wherein setting the programming time period of one of the memory cell groups to overlap with the programming time period of another one of the memory cell groups comprises:
setting a programming time period of each of the memory cell groups in the failure group collection to overlap with a programming time period of a preceding memory cell group in the failure group collection by a predetermined duration.

8. The programming method according to claim 7, wherein sequentially programming the memory cell groups accordingly comprises:
sequentially programming the memory cell groups in the failure group collection during corresponding programming time periods.

9. A flash memory device, comprising:
a memory array having a plurality of memory areas; and
a memory control circuit coupled to the memory array and configured to select a target memory area to be performed a programming operation from the memory areas, wherein the target memory area is divided into a plurality of memory cell groups,
wherein the memory control circuit is configured to perform a programming verification on the target memory area, and
in a case where the target memory area fails the programming verification, the memory control circuit is configured to set a programming time period of one of the memory cell groups to overlap with a programming time period of another one of the memory cell groups, and sequentially program the memory cell groups accordingly.

10. The flash memory device according to claim 9, wherein the memory cell groups respectively correspond to a plurality of masks, and in response to a first one of the masks being opened, the memory control circuit is configured to program only a first one of the memory cell groups, and
after a predetermined duration has passed since the first one of the masks is opened, a second one of the masks is opened so that the memory control circuit simultaneously programs the first one and a second one of the memory cell groups.

11. The flash memory device according to claim 9, wherein the memory control circuit is configured to set a programming time period of each of the memory cell groups to overlap with a programming time period of a preceding memory cell group by a predetermined duration.

12. The flash memory device according to claim 11, wherein the memory control circuit is configured to sequentially program the memory cell groups that fail the programming verification during corresponding programming time periods.

13. The flash memory device according to claim 11, wherein the predetermined duration is half or two-thirds of a length of the programming time period of the memory cell group.

14. The flash memory device according to claim 9, wherein the memory control circuit is configured to add the memory cell groups that fail the programming verification in the target memory area to a failure group collection.

15. The flash memory device according to claim 14, wherein the memory control circuit is configured to set a programming time period of each of the memory cell groups in the failure group collection to overlap with a programming time period of a preceding memory cell group in the failure group collection by a predetermined duration.

16. The flash memory device according to claim 15, wherein the memory control circuit is configured to sequentially program the memory cell groups in the failure group collection during corresponding programming time periods.
